(19) United States
(12) Patent Application Publication
(10) Pub. No.: US 2002/0125534 A1
(43) Pub. Date: Sep. 12, 2002

(54) Semiconductor device having silicon-on-insulator structure and method of fabricating the same

(75) Inventors: Min-Su Kim, Daegu-city (KR); Kwang-Il Kim, Suwon-city (KR)

Correspondence Address: Steven M. Mills, MILLS & ONELLO LLP, Suite 605, Eleven Beacon Street, Boston, MA, 02108, US

(73) Assignee: Samsung Electronics Co., Ltd.

(21) Appl. No.: 09/994,146

(22) Filed: Nov. 26, 2001

(30) Foreign Application Priority Data
Mar. 12, 2001 (KR) 2001-12630

(51) Int. Cl. H01L 27/01

(52) U.S. Cl. 257/347

(57) ABSTRACT

A semiconductor device having a silicon-on-insulator (SOI) structure is provided. The semiconductor device includes: an insulating layer; an insular silicon region having first conductive impurity ions and being formed on the insulating layer; a source region having second conductive impurity ions and being formed at an end of the insular silicon region; a drain region having second conductive impurity ions and spaced apart from the source region at the other end of the insular silicon region; an insular body region which is disposed between the source and drain regions and on which a channel is formed; a body contact region having first conductive impurity ions and being connected to the source region and the insular body region; a conductive layer formed on the source region and the body contact region; and a source electrode in contact with the body contact region on the source region.

### BACKGROUND OF THE INVENTION

1. Field of the Invention

The present invention relates to a semiconductor device and a method of fabricating the same, and more particularly, to a semiconductor device having a silicon-on-insulator (SOI) structure and a method of fabricating the same.

2. Description of the Related Art

A well known SOI structure is a structure in which a relatively thick insulating layer and a single crystal silicon layer are sequentially formed on a semiconductor substrate. A semiconductor device having an SOI structure is an isolated device, which is formed on a single crystal silicon layer. Using the semiconductor device having such SOI structure, it is easy to fabricate semiconductor integrated circuits having high voltage elements and improve the integration density of semiconductor integrated circuits.

However, it is impossible to apply a fixed voltage to an insular body region in a semiconductor device having a conventional SOI structure. Thus, the insular body region is in a floating state and leakage current easily occurs between a source and a drain, thereby rendering electrical characteristics of the device unstable. Thus, methods of applying a fixed voltage to an insular body region in a semiconductor device having an SOI structure have been proposed. The adoption of a body contact structure is representative of the methods of applying a fixed voltage to an insular body region.

FIG. 1A shows a layout of a semiconductor device having a conventional SOI structure adopting a body contact structure. FIG. 1B is a cross-sectional view taken along line IB-IB′ of FIG. 1A. Referring to FIGS. 1A and 1B, an insulating layer 11 is formed on a p⁻ type semiconductor substrate 10. A p⁻ type insular silicon region 12 is formed on the insulating layer 11. An n⁺ type source region 13, an n⁺ type drain region 14, and a p⁻ type body region 15 are formed in the p⁻ type insular silicon region 12. The p⁻ type body region 15 is in an insular state, and a channel may be formed thereon. A p⁺ type body contact region 16 is formed next to the p⁻ type body region 15. Trench isolation layers 17 are formed in regions where the p⁻ type insular silicon region 12 and the p⁺ type body contact region 16 are not formed. A gate insulating layer 18 and a gate conductive layer 19 are sequentially formed on the p⁻ type body region 15. The n⁺ type source region 13 and the n⁺ type drain region 14 are each connected to a source electrode (not shown) and a drain electrode (not shown) via a source contact 13c and a drain contact 14c, respectively. The gate conductive layer 19 is connected to a gate electrode 20 via a gate contact 19c. The p⁺ type body contact region 16 is connected to a body contact electrode 21 via a body contact 16c, and interlayer dielectric layers 22 insulate electrodes 20 and 21 from each other.

In the semiconductor device having a conventional SOI structure, it is possible to apply a fixed voltage such as ground potential to the p⁻ type body region 15 through the body contact electrode 21. However, the area of the semiconductor device is increased by the body contact 16c. In particular, in a case where an application circuit consists of several transistors, body contact regions in proportion to the number of transistors are needed, thereby reducing the integration density of a device.

### SUMMARY OF THE INVENTION

To solve the above problems, it is an object of the present invention to provide a semiconductor device having an SOI structure while maintaining high integration density and being capable of having a predetermined voltage applied to an insular body region of the SOI structure.

It is another object of the present invention to provide a method of fabricating the semiconductor device having an SOI structure.

In accordance with the invention, there is provided a semiconductor device having a silicon-on-insulator (SOI) structure. The semiconductor device includes an insulating layer and an insular silicon region having first conductive impurity ions formed on the insulating layer. A source region having second conductive impurity ions is formed at an end of the insular silicon region. A drain region having second conductive impurity ions is formed to be spaced apart from the source region at the other end of the insular silicon region. An insular body region on which a channel is formed is disposed between the source and drain regions. A body contact region having first conductive impurity ions is formed to be connected to the source region and the insular body region. A conductive layer is formed on the source region and the body contact region. A source electrode is formed to be in contact with the body contact region on the source region.

The body contact region can be formed on one side of the source region. Alternatively, the body contact region may be formed on both sides of the source region.

In one embodiment, the insulating layer is an oxide layer.

The insular silicon region can be a single crystal silicon layer.

The semiconductor device can further include a gate insulating layer formed on the insular body region, a gate conductive layer formed on the gate insulating layer, a gate electrode electrically connected to the gate conductive layer, and a drain electrode electrically connected to the drain region.

The conductive layer can be a salicide layer. The salicide layer can be a cobalt salicide layer, a titanium salicide layer, or a nickel salicide layer.

In one embodiment, the first conductive impurity ions are p-type and the second conductive impurity ions are n-type. Alternatively, the first conductive impurity ions are n-type and the second conductive impurity ions are p-type.

In accordance with another aspect, there is provided in accordance with the invention a method of fabricating a semiconductor device having an SOI structure. In accordance with the method, an SOI structure where a silicon layer having first conductive impurity ions is formed on an insulating layer is prepared. An isolation layer surrounding the silicon layer is formed to form an insular silicon region on the insulating layer. A gate insulating layer is formed to cover a portion of the surface of the insular silicon region. A gate conductive layer is formed on the gate insulating layer. Source and drain regions having second conductive impurity ions are formed on the insular silicon region exposed by the gate conductive layer to define an insular body region between the source and drain regions. A body contact region having first conductive impurity ions is formed to be connected to one side of the source region and the insular body region. A conductive layer is formed on the source region and the body contact region. A source electrode is formed to be connected to the conductive layer on the source region.

The SOI structure can be formed by an expitaxial growth method, a wafer bonding method, or a separation by implanted oxygen (SIMOX) method.

The isolation layer can be formed by a LOCOS isolation method or a trench isolation method.

The conductive layer can be a salicide layer. The salicide layer can be a cobalt salicide layer, a titanium salicide layer, or a nickel salicide layer.

In one embodiment, the first conductive impurity ions are p-type and the second conductive impurity ions are n-type. Alternatively, the first conductive impurity ions are n-type and the second conductive impurity ions are p-type.

### BRIEF DESCRIPTION OF THE DRAWINGS

The foregoing and other objects, features and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIG. 1A is a layout diagram of a semiconductor device having a conventional SOI structure adopting a body contact structure.

FIG. 1B is a cross-sectional view taken along line IB-IB′ of FIG. 1A.

FIG. 2A is a layout diagram of an embodiment of a semiconductor device having an SOI structure according to the present invention.

FIG. 2B is a cross-sectional view taken along line IIB-IIB′ of FIG. 2A.

FIG. 2C is a cross-sectional view taken along line IIC-IIC′ of FIG. 2A.

FIG. 2D is a cross-sectional view taken along line ID-IID′ of FIG. 2A.

FIG. 3 is a layout diagram of an application circuit device formed of a plurality of semiconductor devices such as the semiconductor device shown in FIG. 2A.

FIG. 4A is a layout diagram of another embodiment of a semiconductor device having an SOI structure according to the present invention.

FIG. 4B is a cross-sectional view taken along line IVB-IVB′ of FIG. 4A.

FIG. 4C is a cross-sectional view taken along line IVC-IVC′ of FIG. 4A.

FIG. 4D is a cross-sectional view taken along line IVD-IVD′ of FIG. 4A.

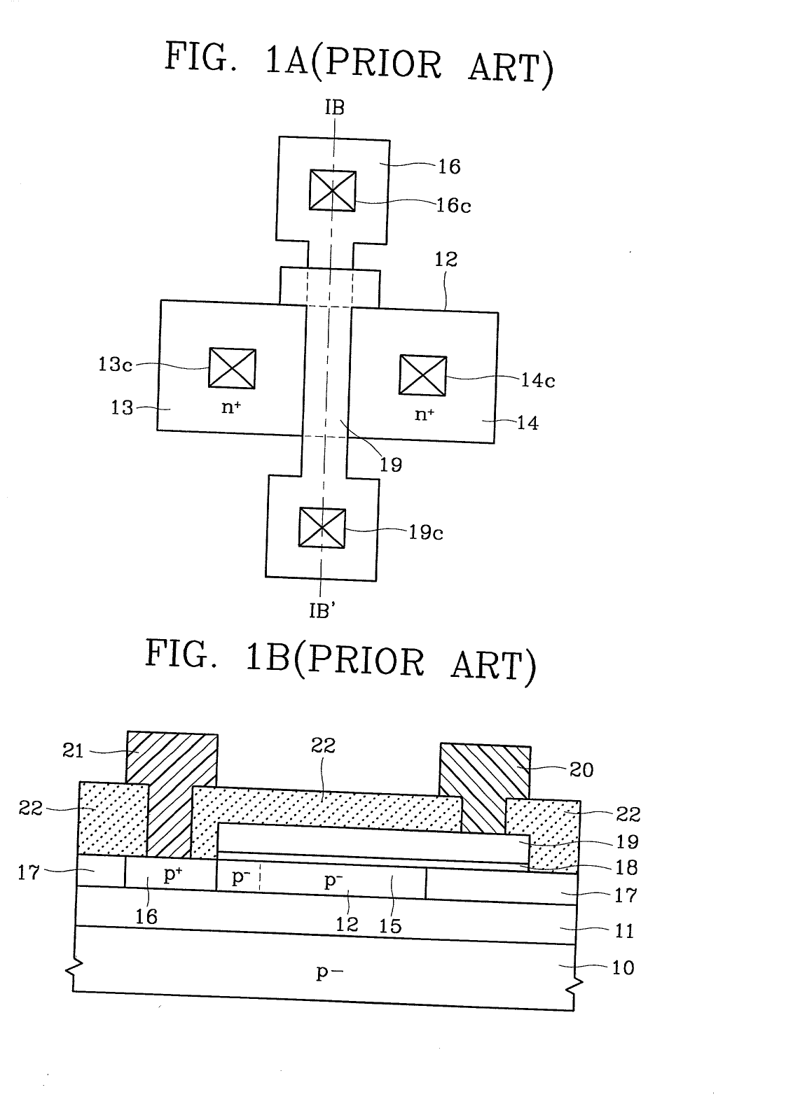

### DESCRIPTION OF THE PREFERRED EMBODIMENTS

Hereinafter, preferred embodiments of the present invention will be described in detail with reference to the attached drawings. In the drawings, the thicknesses of layers or regions are exaggerated for clarity. Also, when it is stated that a layer is formed “on” another layer or a substrate, the layer can be formed directly on the other layer or the substrate, or other layers may intervene therebetween.

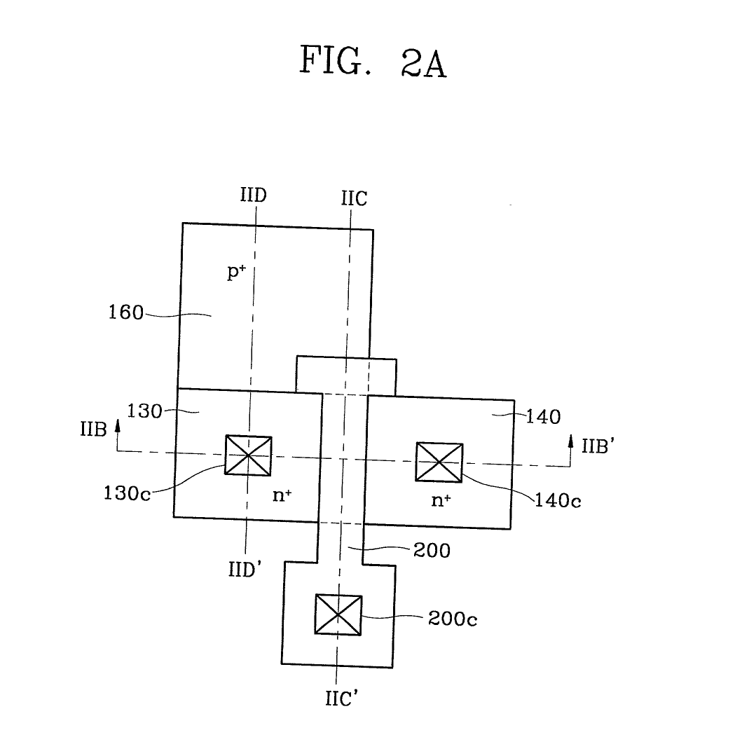

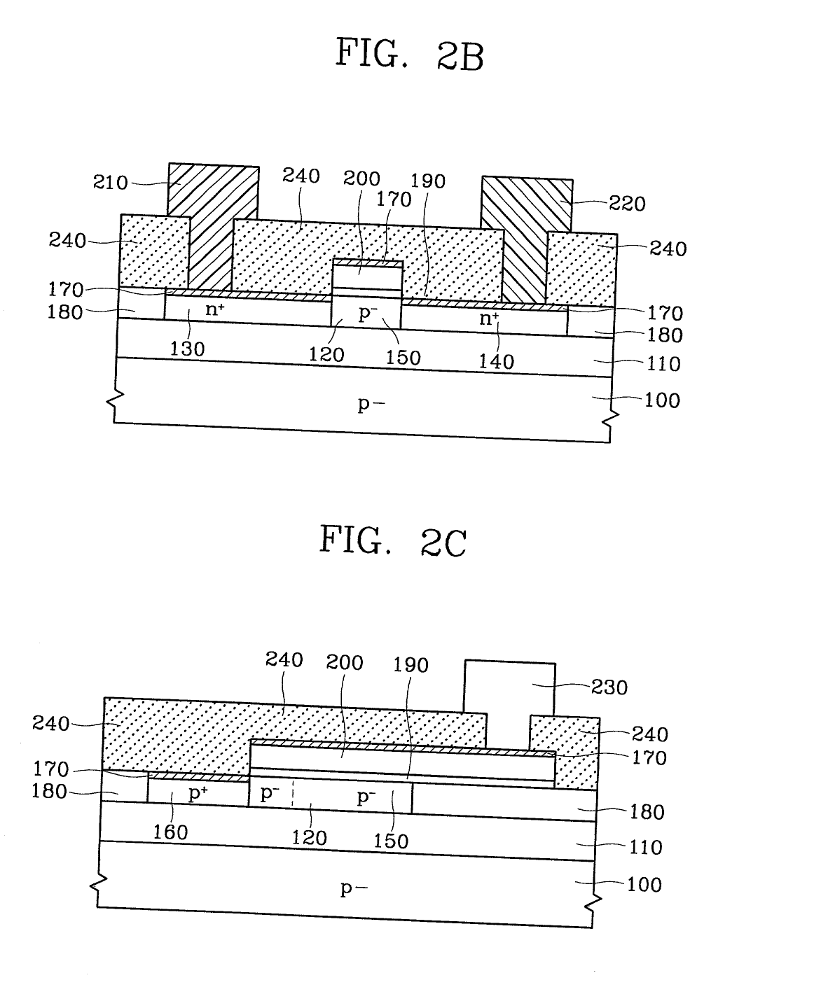

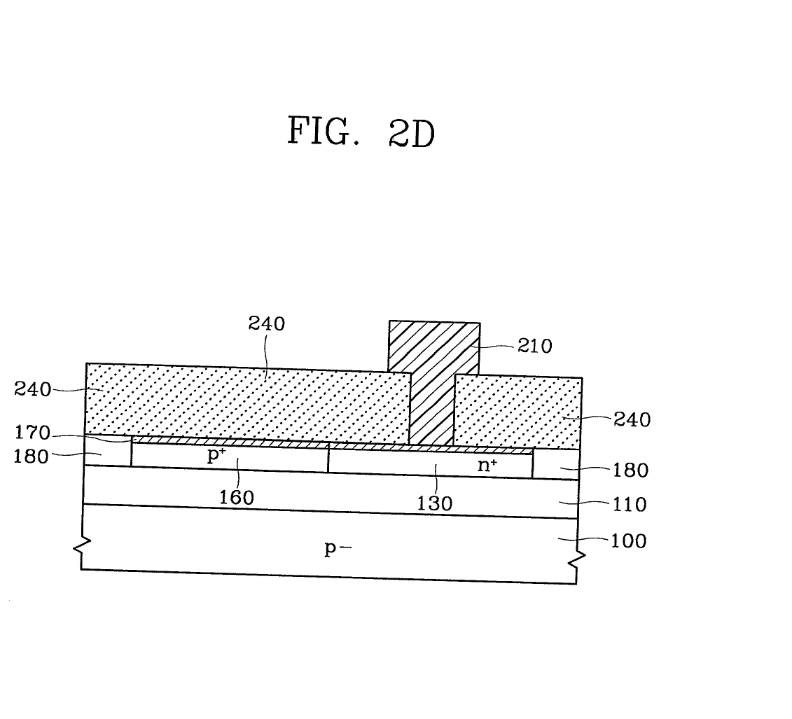

FIG. 2A shows a layout of an embodiment of a semiconductor device having an SOI structure, e.g., an n type transistor having an SOI structure, according to the present invention. FIGS. 2B, 2C, and 2D are each cross-sectional views taken along the lines IIB-IIB′, IIC-IIC′, and IID-IID′, respectively, of FIG. 2A. Referring to FIGS. 2A through 2D, an insulating layer 110 is formed on a p⁻ type semiconductor substrate 100. A p⁻ type insular silicon region 120 is formed of single crystal silicon on the insulating layer 110. An n⁺ type source region 130, an n⁺ type drain region 140, and a p⁻ type body region 150 are formed in the p⁻ type insular silicon region 120. The p⁻ type body region 150 is in an insular state, and a channel may be formed thereon. A p⁺ body contact region 160 is formed next to the n⁺ type source region 130 and the p⁻ type body region 150. The p⁺ type body contact region 160 contacts one side of the n⁺ type source region 130 and one end of the p⁻ type body region 150. A conductive layer, i.e., a salicide layer 170, is formed on the p⁺ type body contact region 160 and the n⁺ type source region 130. The salicide layer 170 is formed of cobalt salicide, titanium salicide, or nickel salicide. Trench isolation layers 180 are formed on the insulating layer 110 in regions where the p⁻ type insular silicon region 120 and the p⁺ type body contact region 160 are not formed. A gate insulating layer 190 and a gate conductive layer 200 are sequentially formed on the p⁻ type body region 150. The n⁺ type source region 130 is connected to a source electrode 210 via a source contact 130c on the salicide layer 170, and the n⁺ type drain region 140 is connected to a drain electrode 220 via the salicide layer 170 and a drain contact 140c. The gate conductive layer 200 is connected to a gate electrode 230 via the salicide layer 170 and a gate contact 200c. An interlayer dielectric layer 240 insulates electrodes 210, 220 and 230 from each other.

The p⁺ type body contact region 160 of the semiconductor device is directly connected to the p⁻ type body region 150 and to the source electrode 210 via the salicide 170. Thus, if the source electrode 210 has a ground potential, the p⁻ type body region 150 has a predetermined ground potential. Also, it is unnecessary to form a separate contact region in the p⁺ type body contact region 160. Thus, the area of a device is reduced to improve the integration of the device. As a result, a layout of a semiconductor device having a general SOI structure can readily be adopted. Only the p⁺ type body contact region 160 is added to a layout used in a semiconductor device having a general SOI structure. The p⁺ type body contact region 160 has a small area due to the absence of an unnecessary separate contact region.

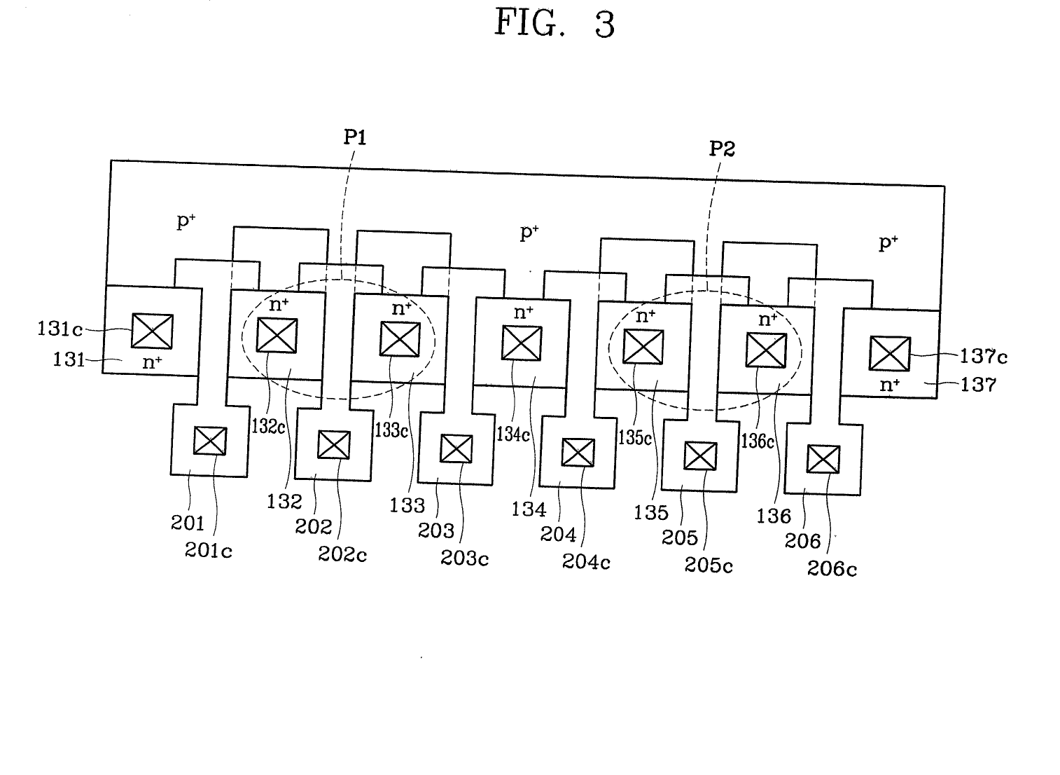

FIG. 3 is a layout of an application circuit device formed of a plurality of semiconductor devices such as the semiconductor device of FIG. 2A. Referring to FIG. 3, in a case where an application circuit device includes six semiconductor devices having SOI structures according to the present invention, e.g., six transistors having SOI structures, first through sixth gate conductive layers 201 through 206 are spaced apart from each other. The first through sixth gate conductive layers 201 through 206 are each connected to gate electrodes via first through sixth gate contacts 201c through 206c. First through seventh n⁺ type regions 131 through 137, which are each used as source or drain regions, are formed at the sides of the first through sixth gate conductive layers 201 through 206. The first, fourth, and seventh n⁺ type regions 131, 134, and 137 are used as source regions having ground potential. The second, third, fifth, and sixth n⁺ type regions 132, 133, 135, and 136 are used as source or drain regions having predetermined voltages depending on a signal applied to the gate electrodes. For example, the second n⁺ type region 132 is used as a drain region in a first transistor having the first gate conductive layer 201 while used as a source region in a second transistor having the second gate conductive layer 202. In the case where the second n⁺ type region 132 is used as the source region in the second transistor, the second n⁺ type region 132 has a predetermined voltage depending on a voltage applied to the gate electrode. The fifth n⁺ type region 135 has the same properties as the second n⁺ type region 132.

Similar to second and fifth transistors having second and fifth gate conductive layers 202 and 205, transistors where source and drain regions have predetermined voltages depending on voltages applied to the gate electrodes are called pass transistors P1 and P2. It is unnecessary to connect the p⁺ type body contact region 160 to source contacts 132c and 135c since the source regions 132 and 135 do not have ground potential in the pass transistors P1 and P2. Thus, the p⁺ type body contact region 160 is connected to grounded source contacts 131c, 134c, and 137c of the transistors and not connected to the pass transistors P1 and P2 while connected to only p⁻ type body regions beneath the gate conductive layers 202 and 205 in the pass transistors P1 and P2. As a result, the p⁻ type body regions of the pass transistors P1 and P2 have predetermined ground potential, thereby forming a variety of application circuits.

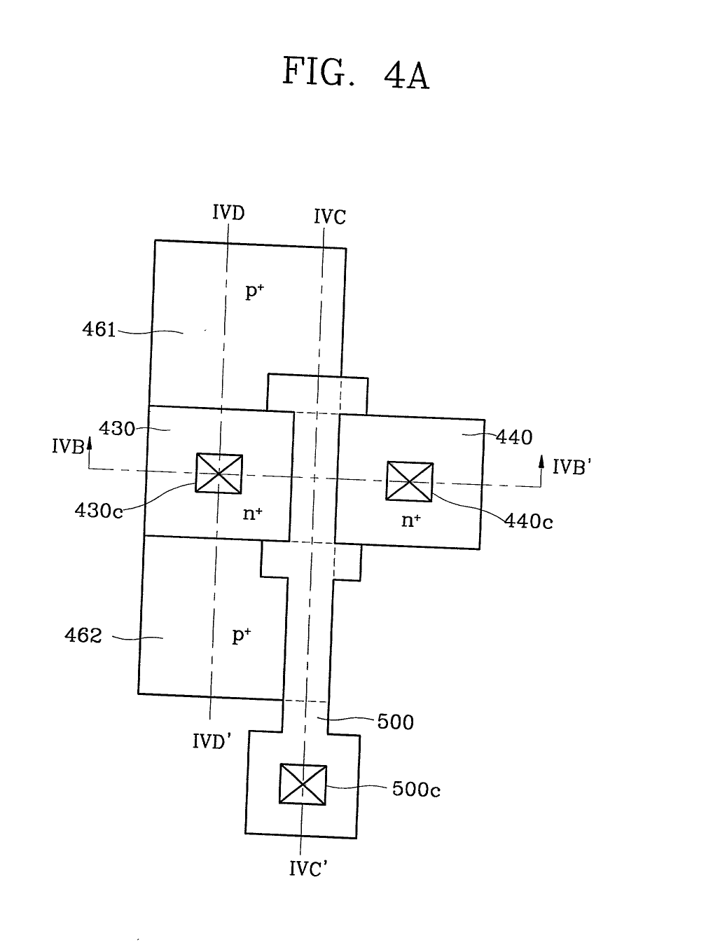

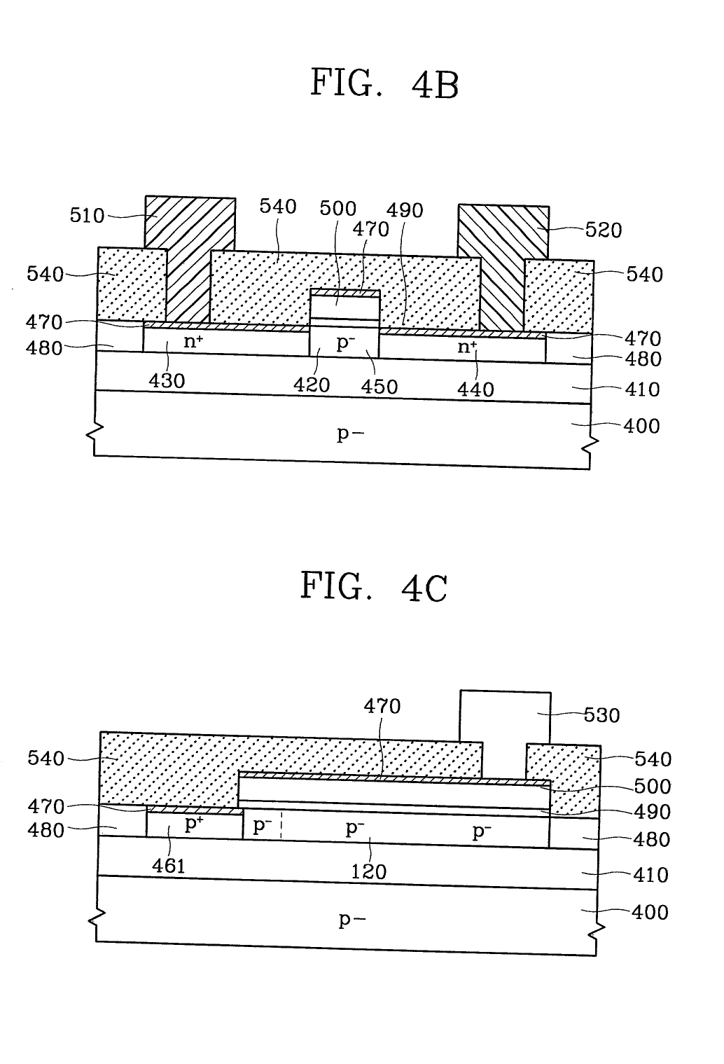

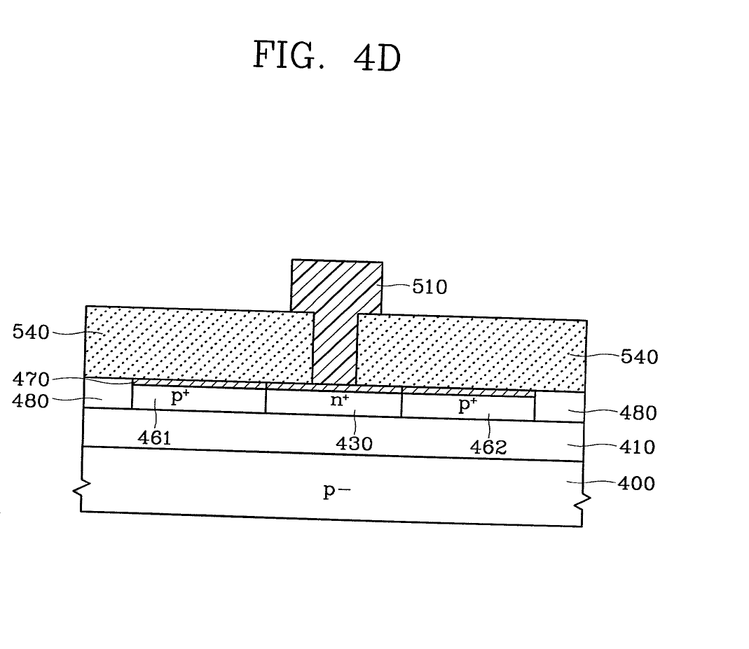

FIG. 4A is a layout of another embodiment of the semiconductor device having an SOI structure according to the present invention. FIGS. 4B, 4C, and 4D are cross-sectional views taken along lines IVB-IVB′, IVC-IVC′, and IVD-IVD′, respectively, of FIG. 4A.

The present embodiment is different from the above-described embodiment in that a p⁺ type body contact region is formed at both sides of an n⁺ type source region. In other words, as shown in FIGS. 4A through 4D, an insulating layer 410 is formed on a p⁻ type semiconductor substrate 400. A p⁻ type insular silicon region 420 is formed of single crystal silicon on the insulating layer 410. An n⁺ type source region 430, an n⁺ type drain region 440, and a p⁻ type body region 450 are formed in the p⁻ type insular silicon region 420. P⁺ type body contact regions 461 and 462 are formed next to the n⁺ type source region 430 and the p⁻ type body region 450. The p⁺ type body contact regions 461 and 462 contact both sides of the n⁺ type source region 430 as well as both ends of the p⁻ type body region 450. As described, the p⁺ type body contact regions 461 and 462 contact both sides of the n⁺ type source region 430, thereby ensuring a path of carriers accumulated in the p⁻ type body region 450, i.e., holes, and inhibiting a floating body effect. In particular, in a case where a transistor is wide, i.e., the path of holes is long, the floating body effect is inhibited more considerably.

A salicide layer 470 is formed on the p⁺ type body contact regions 461 and 462 and the n⁺ type source region 430. The salicide layer 470 is preferably formed of cobalt salicide, titanium salicide, or nickel salicide or may also be formed of similar materials. Trench isolation layers 480 are formed on the insulating layer 410 in regions where the p⁻ type insular silicon region 420 and the p⁺ type body contact region 460 are not formed. A gate insulating layer 490 and a gate conductive layer 500 are sequentially formed on the p⁻ type body region 450. The n⁺ type source region 430 is connected to a source electrode 510 via a source contact 430c on the salicide layer 470. The n⁺ type drain region 440 is connected to a drain electrode 520 via the salicide layer 470 and a drain contact 440c. The gate conductive layer 500 is connected to a gate electrode 530 via the salicide layer 470 and a gate contact 500c. An interlayer dielectric layer 540 insulates electrodes 510, 520 and 530 from each other.

In the semiconductor device, the p⁺ type body contact regions 461 and 462 are directly connected to the p⁻ type body region 450 and to the source electrode 510 via the salicide layer 470. Thus, if the source electrode 510 has ground potential, the p⁻ type body region 450 has a predetermined ground potential. Also, it is unnecessary to form separate contact regions in the p⁺ type body contact regions 461 and 462. Thus, the area of a device is reduced to improve the integration of the device, and a layout of a semiconductor device having a general SOI structure can readily be adopted. Only the p⁺ type body contact regions 461 and 462 are added to a layout used in a semiconductor device having a general SOI structure. The p⁺ type body contact regions 461 and 462 have small areas due to the absence of unnecessary separate contact regions.

Although the n-channel transistor having an SOI structure has been described, it will be apparent that a p-channel transistor having an SOI structure provides the same effect as the n-channel transistor. However, a semiconductor substrate and a body region have n⁻ type conductive impurity ions, source and drain regions have p⁺ type conductive impurity ions, and a body contact region have n⁺ type conductive impurity ions.

Hereinafter, a method of fabricating the semiconductor device having an SOI structure according to the present invention will be described with reference to FIGS. 2A through 2D. An insulating layer 110 is formed on a p⁻ type semiconductor substrate 100 formed of silicon. The insulating layer 110 may be formed of oxide. A p⁻ type silicon region 120 is formed on the insulating layer 110. The p⁻ type silicon region 120 may be formed by implanting p-type impurity ions into a single crystal layer and epitaxially growing it. In other words, a wafer bonding method or a separation by implanted oxygen (SIMOX) method may be used. Isolation layers 180 are formed by a general isolation method to define the p⁻ type silicon region 120. The isolation layers 180 are trench isolation layers but may formed by a local oxidation of silicon (LOCOS) method. An oxide layer and a conductive layer are sequentially formed and then patterned using a general mask layer pattern, thereby forming a gate insulating layer 190 and a gate conductive layer 200.

N⁻ type impurity ions are implanted into a region where n⁺ type source and drain regions 130 and 140 will be formed, using a mask layer pattern exposing both sides of the gate insulating layer 190 and the gate conductive layer 200 as ion implantation masks. After the mask layer pattern is removed, p⁻ type impurity ions are implanted into a region where a p⁺ type body contact region 160 and an n⁺ type source region 130 will be formed, using a mask layer pattern exposing one side of the region and the gate conductive layer 200 as ion implantation masks. The mask layer pattern is removed and n⁻ type and p⁻ type-impurity ions are diffused to form an n⁺ type source region 130, an n⁺ type drain region 140, and a p⁺ type body contact region 160. An interlayer dielectric layer is formed, and then a portion thereof is etched to form a source contact hole 130c, a drain contact hole 140c, and a gate contact hole 200c. A source electrode 210, a drain electrode 220, and a gate electrode 230 are formed to fill the source, drain, and gate contact holes 130c, 140c, and 200c, respectively.

Although an n-channel transistor having an SOI structure has been described, it will be apparent that a p-channel having an SOI structure uses the same method as the n-channel transistor. However, a semiconductor substrate and a body region have n⁻ type conductive impurity ions, source and drain regions have p⁺ type conductive impurity ions, and a body contact have n⁺ type conductive impurity ions in the p-channel transistor having the SOI structure. In a case where an n-type transistor and a p-type transistor are complementary to each other, n⁺ type source and drain regions of the n-type transistor are simultaneously formed with a body contact region of the p-type transistor. Also, a p⁺ type body contact region of the n-type transistor is simultaneously formed with p⁺ type source and drain regions of the p-type transistor.

A method of fabricating the semiconductor device having an SOI structure according to another embodiment of the present invention shown in FIGS. 4A through 4D is similar to the embodiment shown in FIGS. 2A through 2D except that a mask layer pattern exposing both sides of an n⁺ type source region 430 is used as an ion implantation mask when implanting p⁻ type impurity ions to form a p⁺ type body contact region 460.

As described above, there are advantages in the semiconductor device having an SOI structure and a method of fabricating the same according to the present invention.

First, since a body contact region is connected to a source electrode via a salicide layer, it is unnecessary to form a separate body contact region in a body contact. Thus, the integration of a device can be improved.

Second, only an additional body contact region is formed. Thus, a layout used in a semiconductor device having a general SOI structure can readily be adopted without making many modifications.

Third, the body contact region serves as a path for carriers accumulated in an insular body contact. Thus, a floating body effect is prevented.

Fourth, in the case of a pass transistor where both source and drain regions do not have ground potential, a body contact region is connected to a source contact of a transistor adjacent to the pass transistor. Thus, an insular body region of the pass transistor can be supplied with ground potential.

While this invention has been particularly shown and described with reference to preferred embodiments thereof, it will be understood by those skilled in the art that various changes in form and details may be made therein without departing from the spirit and scope of the invention as defined by the appended claims.

What is claimed is:

1. A semiconductor device having a silicon-on-insulator (SOI) structure, comprising:
an insulating layer;
an insular silicon region having first conductive impurity ions formed on the insulating layer;
a source region having second conductive impurity ions formed at an end of the insular silicon region;
a drain region having second conductive impurity ions spaced apart from the source region at the other end of the insular silicon region;
an insular body region which is disposed between the source and drain regions and on which a channel is formed;
a body contact region having first conductive impurity ions and connected to the source region and the insular body region;
a conductive layer formed on the source region and the body contact region; and
a source electrode in contact with the body contact region on the source region.

2. The semiconductor device of claim 1, wherein the body contact region is formed on one side of the source region.

3. The semiconductor device of claim 1, wherein the body contact region is formed on both sides of the source region.

4. The semiconductor device of claim 1, wherein the insulating layer is an oxide layer.

5. The semiconductor device of claim 1, wherein the insular silicon region is a single crystal silicon layer.

6. The semiconductor device of claim 1, further comprising:
a gate insulating layer formed on the insular body region;
a gate conductive layer formed on the gate insulating layer;
a gate electrode electrically connected to the gate conductive layer; and
a drain electrode electrically connected to the drain region.

7. The semiconductor device of claim 1, wherein the conductive layer is a salicide layer.

8. The semiconductor device of claim 7, wherein the salicide layer is one of a cobalt salicide layer, a titanium salicide layer, and a nickel salicide layer.

9. The semiconductor device of claim 1, wherein the first conductive impurity ions are p-type and the second conductive impurity ions are n-type.

10. The semiconductor device of claim 1, wherein the first conductive impurity ions are n-type and the second conductive impurity ions are p-type.

11. A method of fabricating a semiconductor device having an SOI structure, comprising:
preparing an SOI structure where a silicon layer having first conductive impurity ions is formed on an insulating layer;
forming an isolation layer surrounding the silicon layer to form an insular silicon region on the insulating layer;
forming a gate insulating layer covering a portion of the surface of the insular silicon region;
forming a gate conductive layer on the gate insulating layer;
forming source and drain regions having second conductive impurity ions on the insular silicon region exposed by the gate conductive layer to define an insular body region between the source and drain regions;
forming a body contact region having first conductive impurity ions to be connected to one side of the source region and the insular body region;
forming a conductive layer on the source region and the body contact region; and
forming a source electrode to be connected to the conductive layer on the source region.

12. The method of claim 11, wherein the SOI structure is formed by one of an expitaxial growth method, a wafer bonding method, and a separation by implanted oxygen (SIMOX) method.

13. The method of claim 11, wherein the isolation layer is formed by one of a LOCOS isolation method and a trench isolation method.

14. The method of claim 11, wherein the conductive layer is a salicide layer.

15. The method of claim 14, wherein the salicide layer is one of a cobalt salicide layer, a titanium salicide layer, and a nickel salicide layer.

16. The method of claim 11, wherein the first conductive impurity ions are p-type and the second conductive impurity ions are n-type.

17. The method of claim 11, wherein the first conductive impurity ions are n-type and the second conductive impurity ions are p-type.
